(19) United States
(12) Patent Application Publication
(10) Pub. No.: US 2001/0004135 A1
(43) Pub. Date: Jun. 21, 2001

(54) Flip-chip bonded semiconductor device

(76) Inventor: Ryuichi Okamura, Tokyo (JP)

Correspondence Address: Paul-J. Esatto, Jr., Scully, Scott, Murphy & Presser, 400 Garden City Plaza, Garden City, NY, 11530, US

(21) Appl. No.: 09/741,605

(22) Filed: Dec. 19, 2000

(30) Foreign Application Priority Data
Dec. 20, 1999 (JP) 11-360523

(51) Int. Cl. H01L 23/48; H01L 23/52; H01L 29/40

(52) U.S. Cl. 257/778

(57) ABSTRACT

A semiconductor chip is mounted on a printed wiring board (PWB), with the pads of the semiconductor chip mounted on the electrodes of the PWB for flip-chip bonding. The density of the pads in the peripheral area is higher or lower compared to the density of the pads in the central area depending on the thermal shrinkage factor of the PWB being higher or lower compared to the thermal shrinkage factor of the semiconductor chip.

### BACKGROUND OF THE INVENTION

(a) Field of the Invention

The present invention relates to a flip-chip bonded semiconductor device and, more particularly, to a semiconductor device having a semiconductor chip mounted on a printed wiring board by a flip-chip bonding technique.

(b) Description of the Related Art

Flip-chip bonding technique is increasingly used in a semiconductor device for mounting a semiconductor chip on a printed wiring board (PWB). FIG. 1 shows a bottom view of a conventional semiconductor chip to be mounted on a PWB by the flip-chip bonding technique. A plurality of pads 30 are arranged on the entire bottom surface of the semiconductor chip 10 in a matrix at a uniform pitch and a uniform density.

In the semiconductor device wherein the semiconductor chip 10 is mounted on a PWB by the flip-chip bonding technique, the semiconductor chip 10 is liable to a stress concentration at a specified part of pads 30 and suffers from reduction of the reliability in the electrical connection between the pads of the semiconductor chip and the electrodes of the PWB.

### SUMMARY OF THE INVENTION

In view of the above, it is an object of the present invention to provide a flip-chip bonded semiconductor device wherein a semiconductor chip is mounted on a PWB with a higher reliability in electrical connection, by alleviating the stress concentration on the specified part of the pads on the semiconductor chip.

The present invention provides a semiconductor device including a semiconductor chip having a plurality of pads thereon, and a board having a plurality of electrodes each mounting thereon one of the pads of the semiconductor chip for flip-chip bonding, wherein the pads are arranged so that the density of the pads is different between the central area and the peripheral area of the semiconductor chip.

The density of the pads may be higher in the central area of the semiconductor chip than in the peripheral area thereof, or may be lower in the central area of the semiconductor chip than in the peripheral area thereof.

The difference in the density of the pads may be implemented by a difference in the pitch of the arrangement of the pads between both the areas or by subtracting a specified number of pads in either the area from the pads, which are uniformly arranged in both the areas.

The above and other objects, features and advantages of the present invention will be more apparent from the following description, referring to the accompanying drawings.

### BRIEF DESCRIPTION OF THE DRAWINGS

FIG. 1 is a bottom plan view of a conventional semiconductor chip mounting thereon an array of pads.

FIG. 2 is a schematic side view of a general semiconductor device having a semiconductor chip mounted on a PWB.

FIG. 3 is a schematic side view of a conventional semiconductor device including a PWB having a thermal shrinkage factor higher than that of the semiconductor chip.

FIG. 4 is a schematic side view of a conventional semiconductor device including a PWB having a thermal shrinkage factor lower than that of the semiconductor chip.

FIG. 5 is a bottom plan view of a semiconductor chip according to a first embodiment of the present invention.

FIG. 6 is a bottom plan view of a semiconductor chip according to a second embodiment of the present invention.

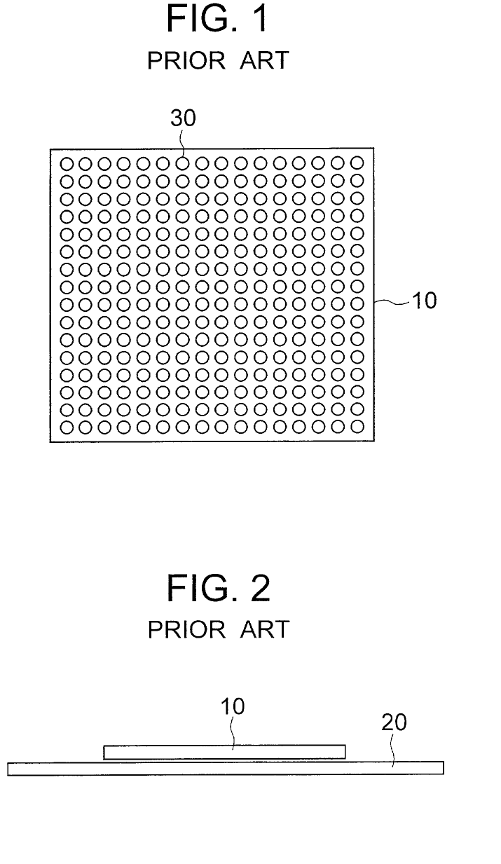

### PREFERRED EMBODIMENTS OF THE INVENTION

Now, the principle of the present invention will be described with reference to accompanying drawings before describing preferred embodiments of the present invention. In the accompanying drawings, similar constituent elements are designated by similar reference numerals throughout the drawings.

Referring to FIG. 2 showing a typical structure of a general semiconductor device, a semiconductor chip 10 is mounted on a PWB or PCB (printed circuit board) 20, with the pads of the semiconductor chip 10 mounted on the respective electrodes of the PWB 20 by a flip-chip bonding technique.

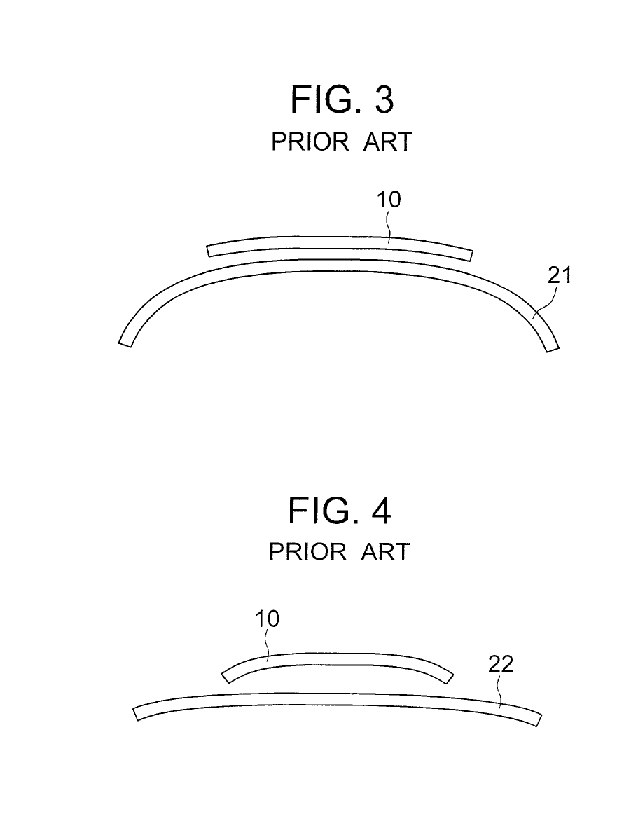

Assuming that the PWB 20 is made of a material having a thermal shrinkage factor higher than that of the material for the semiconductor chip 10, i.e. silicon, in the structure of FIG. 2, the structure is changed to that shown in FIG. 3 due to the thermal shrinkage when a heat cycle test is applied to the semiconductor device.

More specifically, in FIG. 3, although both the semiconductor chip 10 and the PWB 21 are subjected to warp, the degree of the warp is larger in the PWB 21. Thus, the central area of the PWB 21 is raised, whereby a stress concentration is generated in the semiconductor device at the peripheral area of the semiconductor chip 10. This causes a damage of the electrical connection between the pads of the semiconductor chip 10 and electrodes of the PWB 21 starting from the location of the stress concentration at the peripheral area of the semiconductor chip 10.

On the other hand, if the PWB 20 is made of a material having a thermal shrinkage factor lower than that of silicon in the structure of FIG. 2, the structure is changed to that shown in FIG. 4 when a heat cycle test is applied to the semiconductor device.

More specifically, although both the semiconductor chip 10 and the PWB 22 are subjected to warp, the degree of the warp is larger in the semiconductor chip 10. Thus, the central area of the semiconductor chip 10 is raised due to the stress concentration therein. This causes a damage of the electrical connection starting from the location of the stress concentration at the central area of the semiconductor chip 10.

In the present invention, by employing a higher density of the pads in the area of the stress concentration, the stress concentration is alleviated by dispersion thereof to thereby improve the reliability of the electrical connection between the semiconductor chip and the board.

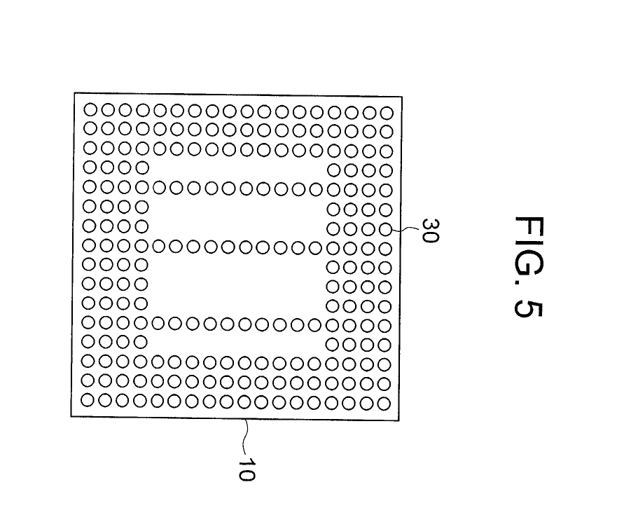

Now, preferred embodiments of the present invention will be described with reference to the drawings. Referring to FIG. 5, a semiconductor chip 10 in a semiconductor device according to a first embodiment of the present invention mounts thereon an array of pads 30 on the bottom surface thereof. The semiconductor chip 10 is to be mounted on a board, such as PWB 20 shown in FIG. 2, made of a material having a thermal shrinkage factor higher than that of the semiconductor chip 10.

The pads 30 are arranged at a higher density in the peripheral area compared to the central area, wherein specified number of pads 30 are removed in the central area from the pads that are arranged at a uniform pitch in both the central and the peripheral areas.

By employing a higher density of pads 30 in the peripheral area, wherein the stress is to be concentrated in a heat cycle test, compared to the central area, the thermal stress per one pad is balanced in the entire area. Thus, the stress concentration in the peripheral area is alleviated, whereby a semiconductor device having a higher reliability in the electrical connection thereof can be obtained.

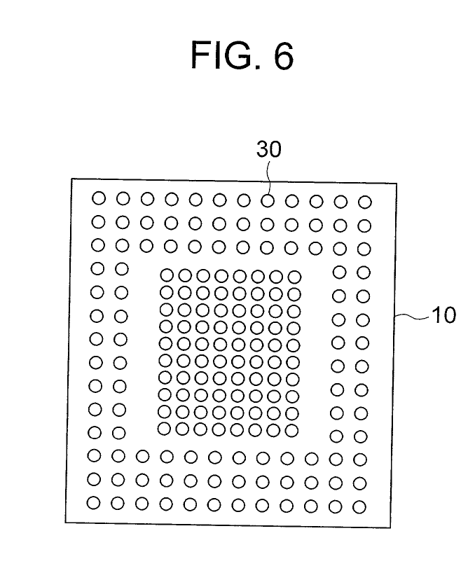

Referring to FIG. 6 showing a bottom surface of a semiconductor chip 10 in a semiconductor device according to a second embodiment of the present invention, the density of pads 30 is larger in the central area compared to that in the peripheral area. The board on which the semiconductor chip 10 is to be mounted is made of a material having a thermal shrinkage factor lower than that of the semiconductor chip 10. In this case, the stress concentration in the central area is alleviated by a higher density of the pads 30 in the central area. That is, the higher density of the pads 30 in the central area balances the thermal stress per one pad due to dispersion of the stress.

The higher density of the pads 30 in the central area is achieved by a smaller pitch of the arrangement of the pads 30 in the central area compared to the arrangement of the pads 30 in the peripheral area.

Since the above embodiments are described only for examples, the present invention is not limited to the above embodiments and various modifications or alterations can be easily made therefrom by those skilled in the art without departing from the scope of the present invention.

What is claimed is:

1. A semiconductor device comprising a semiconductor chip having a plurality of pads, and a board having a plurality of electrodes each mounting thereon one of the pads of the semiconductor chip for flip-chip bonding, wherein the pads are arranged so that a density of the pads is different between a central area and a peripheral area of the semiconductor chip.

2. The semiconductor device as defined in claim 1, wherein the density of the pads is higher in the peripheral area than in the central area.

3. The semiconductor device as defined in claim 2, wherein a specified number of pads are removed in the central area from the pads arranged at a constant pitch in both the central and peripheral areas.

4. The semiconductor device as defined in claim 2, wherein the pads are arranged at a larger pitch in the central area than in the peripheral area.

5. The semiconductor device as defined in claim 2, wherein the board is made of a material having a higher thermal shrinkage factor compared to the semiconductor device.

6. The semiconductor device as defined in claim 1, wherein the density of the pads is higher in the central area than in the peripheral area.

7. The semiconductor device as defined in claim 6, wherein a specified number of pads are removed in the peripheral area from the pads arranged at a constant pitch in both the central and peripheral areas.

8. The semiconductor device as defined in claim 6, wherein the pads are arranged at a smaller pitch in the central area than in the peripheral area.

9. The semiconductor device as defined in claim 6, wherein the board is made of a material having a lower thermal shrinkage factor compared to the semiconductor device.
